(19) United States
(12) Patent Application Publication
(10) Pub. No.: US 2026/0309815 A1
(43) Pub. Date: Oct. 8, 2026

(54) HALL SENSOR

(71) Applicant: Cirrus Logic International Semiconductor Ltd., Edinburgh (GB)

(72) Inventors: John P. LESSO, Edinburgh (GB); James T. DEAS, Edinburgh (GB)

(73) Assignee: Cirrus Logic International Semiconductor Ltd., Edinburgh (GB)

(21) Appl. No.: 19/324,825

(22) Filed: Sep. 10, 2025

Related U.S. Application Data
(60) Provisional application No. 63/783,297, filed on Apr. 4, 2025.

(51) Int. Cl. G01R 33/07; G01R 33/00; H10N 52/00; H10N 52/85

(52) U.S. Cl. CPC G01R 33/07; G01R 33/0029; H10N 52/101; H10N 52/85; G01R 33/0041

(57) ABSTRACT

A Hall sensor comprising: a Hall element configured to generate a Hall voltage in response to a magnetic field; first and second sets of sense electrodes for detecting the Hall voltage, wherein: the first set of sense electrodes comprises a first plurality of separate sense electrodes that are electrically isolated from each other; and the second set of sense electrodes comprises a second plurality of separate sense electrodes that are electrically isolated from each other.

### FIELD OF THE INVENTION

The present disclosure relates to a Hall sensor.

### BACKGROUND

A Hall sensor is a device that measures the presence and magnitude of a magnetic field using the Hall effect. When a current-carrying conductor or semiconductor is placed in a perpendicular magnetic field B, a voltage difference is induced across the current-carrying conductor or semiconductor due to the deflection of charge carriers (electrons or holes). This voltage, known as the Hall voltage VH, is given by:

$$V H = IB / qnd , \qquad ( 1 )$$

where I is the applied current, B is the field strength of the perpendicular magnetic field, q is the elementary charge, n is the charge carrier density, and d is the thickness of the sensor.

Hall sensors are widely used for magnetic field sensing in industrial, automotive, and electronic applications. A common application for Hall sensors is in mobile telephones, tablet computers and the like, where a Hall sensor is used to facilitate electronic compass functionality.

### SUMMARY

According to a first aspect, the invention provides a Hall sensor comprising: a Hall element configured to generate a Hall voltage in response to a magnetic field; first and second sets of sense electrodes for detecting the Hall voltage, wherein: the first set of sense electrodes comprises a first plurality of separate sense electrodes that are electrically isolated from each other; and the second set of sense electrodes comprises a second plurality of separate sense electrodes that are electrically isolated from each other.

The Hall sensor may further comprise: first adder circuitry configured to generate a first adder output signal indicative of a sum of output signals of the first plurality of separate sense electrodes; and second adder circuitry configured to generate a second adder output signal indicative of a sum of output signals of the second plurality of separate sense electrodes.

The Hall sensor may further comprise subtractor circuitry configured to generate a subtractor output signal indicative of a difference between the first and second adder output signals.

The Hall sensor may further comprise differential summing amplifier circuitry configured to generate an amplifier output signal indicative of a difference between a sum of output signals of the first plurality of separate sense electrodes and a sum of output signals of the second plurality of separate sense electrodes.

The Hall sensor may further comprise buffer circuitry coupled between outputs of the first and second sets of sense electrodes and inputs of the differential summing amplifier circuitry.

The first and second sets of set of sense electrodes may be symmetrically disposed about a direction of bias current flow through the Hall element.

Sense electrodes of the first set may be disposed at outer corners or vertices of the first side of the Hall element. Sense electrodes of the second set may be disposed at outer corners or vertices of the second side of the Hall element.

Sense electrodes of the first set may be disposed at inner corners or vertices of the first side of the Hall element. Sense electrodes of the second set may be disposed at inner corners or vertices of the second side of the Hall element.

The Hall sensor may further comprise first and second bias electrodes for supplying a bias current or voltage to the Hall element.

The first and second sets of sense electrodes may be disposed along a first axis. The first and second bias electrodes may be disposed along a second axis orthogonal to the first axis.

The Hall sensor may further comprise first and second sets of bias electrodes for supplying a bias current or voltage to the Hall element. The first set of bias electrodes may comprise a first plurality of separate bias electrodes that are electrically isolated from each other. The second set of sense electrodes may comprise a second plurality of separate bias electrodes that are electrically isolated from each other. The first set of sense electrodes, the second set of sense electrodes, the first set of bias electrodes and the second set of bias electrodes may each comprise an equal number of electrodes.

The first set of sense electrodes, the second set of sense electrodes, the first set of bias electrodes and the second set of bias electrodes may each comprise an even number of electrodes.

A configuration and positioning of the first and second sets of bias electrodes relative to the Hall element may be similar to or correspond to a configuration and positioning of the first and second sets of sense electrodes relative to the Hall element.

The first adder circuitry may be configured to perform a weighted sum of the output signals of the first plurality of separate sense electrodes. The second adder circuitry may be configured to perform a weighted a sum of the output signals of the second plurality of separate sense electrodes to reduce offset in an output signal of the Hall sensor indicative of the Hall voltage.

The Hall element may comprise a planar element having a defined geometry.

For example, the Hall element may be in the form of a cross-or plus-shaped polygon.

The Hall element may be of a Gallium Nitride (GaN) construction.

According to a second aspect, the invention provides an integrated circuit comprising the Hall sensor of the first aspect.

According to a third aspect, the invention provides a host device comprising the Hall sensor of the first aspect.

The host device may comprise a laptop, notebook, netbook or tablet computer, a gaming device, a games console, a controller for a games console, a virtual reality (VR) or augmented reality (AR) device, a mobile telephone, a portable audio player, a portable device, an accessory device for use with a laptop, notebook, netbook or tablet computer, a gaming device, a games console, a VR or AR device, a mobile telephone, a portable audio player or other portable device.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### BRIEF DESCRIPTION OF DRAWINGS

Embodiments of the invention will now be described, strictly by way of example only, with reference to the accompanying drawings, of which:

FIG. 1 is a schematic representation of a Hall sensor arrangement;

FIG. 2 is a schematic representation of an alternative Hall sensor arrangement;

FIG. 3 is a schematic representation of a Hall sensor arrangement according to the present disclosure;

FIG. 4 is a schematic representation of an alternative Hall sensor arrangement according to the present disclosure;

FIG. 5 is a schematic representation of a further alternative Hall sensor arrangement according to the present disclosure;

FIG. 6 is a schematic representation of a further alternative Hall sensor arrangement according to the present disclosure;

FIG. 7 is a schematic representation of a further alternative Hall sensor arrangement according to the present disclosure; and

FIG. 8 is a schematic representation of a further alternative Hall sensor arrangement according to the present disclosure.

### DETAILED DESCRIPTION

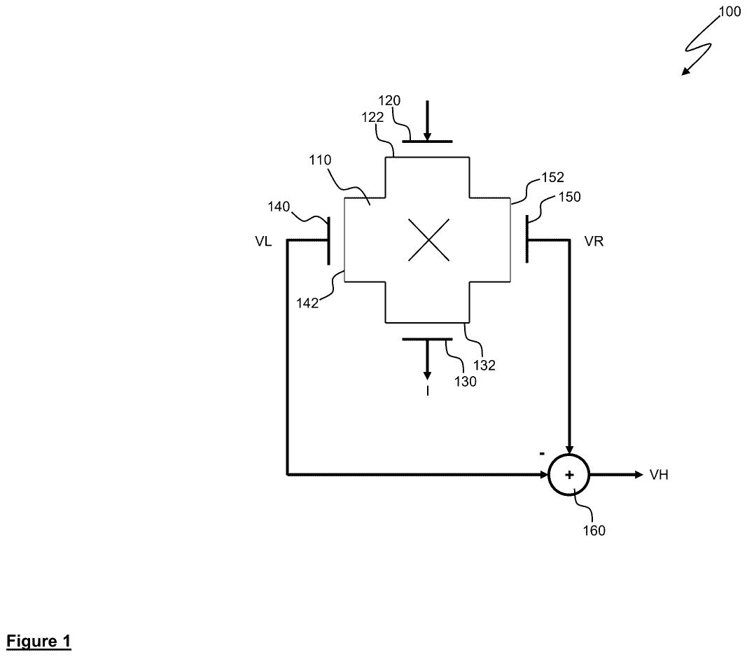

FIG. 1 is a schematic representation of a Hall sensor arrangement.

The Hall sensor arrangement, shown generally at 100 in FIG. 1, comprises a Hall element 110 of a conductor or semiconductor material.

A first bias or drive electrode 120 is disposed at a first side 122 (in this example an upper side) of the Hall element 110 and a second bias or drive electrode 130 is disposed at a second side 132 (in this example a lower side) of the Hall element 110. The first and second bias or drive electrodes 120, 130 are disposed along a first axis.

A first sense electrode 140 is provided at a third side 142 (in this example a left side) of the Hall element 110 and a second sense electrode 150 is provided at a fourth side (in this example a right side) of the Hall element 110. The first and second sense electrodes 140, 150 are disposed along a second axis, orthogonal or perpendicular to the first axis.

The Hall sensor arrangement 100 further includes a subtractor 160 configured to subtract a voltage VL at the first sense electrode 140 from a voltage VR at the second sense electrode 150.

In use of the Hall sensor arrangement 100, a bias current I (or a bias voltage) is supplied to the Hall element 110 and a current flows through the Hall element 110 between the first and second bias or drive electrodes 120, 130. When the Hall element 110 is placed in a magnetic field, the Hall voltage VH develops between the first and second sense electrodes 140, 150. The subtractor 160 subtracts the voltage VL at the first sense electrode 140 from the voltage VR at the second sense electrode 150 and outputs the Hall voltage VH, e.g. to downstream processing circuitry (not shown in FIG. 1).

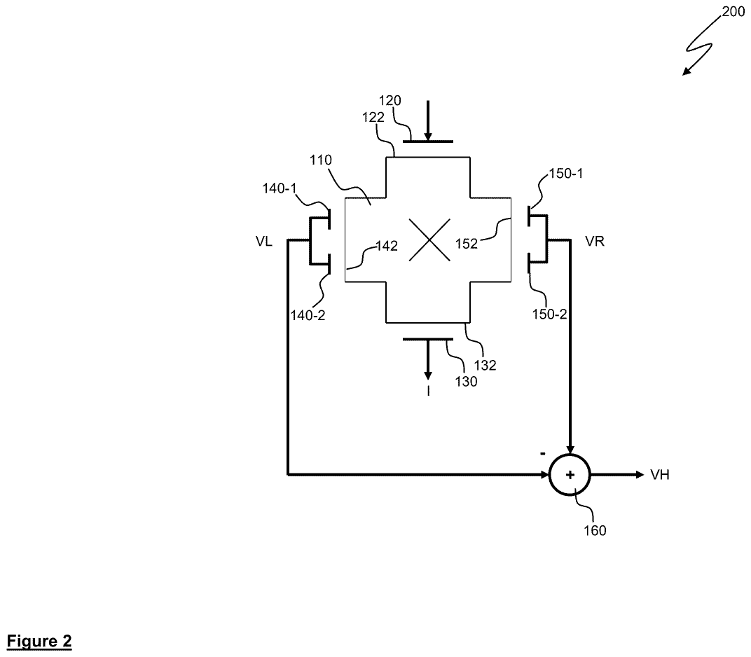

FIG. 2 is a schematic representation of alternative Hall sensor arrangement.

The Hall sensor arrangement shown generally at 200 in FIG. 2 is similar to the Hall sensor arrangement 1 of FIG. 1, and so like elements are denoted by like reference numerals in FIGS. 1 and 2.

The Hall sensor arrangement 200 of FIG. 2 differs from the Hall sensor arrangement 100 of FIG. 1 in that, instead of having a single first sense electrode 140 and a single second sense electrode 150 on opposed first and second sides of the Hall element 110, the Hall sensor arrangement 200 has a first sense electrode comprising a plurality (here two) of separate electrode portions 140-1, 140-2 that are coupled together on the third side 142 of the Hall element 110, and a second sense electrode comprising a plurality (here two) of separate electrode portions 150-1, 150-2 that are coupled together on the fourth side 152 of the Hall element 110, to enhance the measurement of the Hall voltage VH. The coupling of the separate electrode portions of the first and second sense electrodes gives rise to an effect know as contact non-linearity, in which the current flow inside the Hall sensor is modified by the two electrodes enforcing the same electrical potential at two different points on a side or edge of the Hall element 110.

In Hall sensor arrangements of the kind shown in FIGS. 1 and 2, the Hall voltage VH is determined based on the potential difference between two opposed sense electrodes. However, this approach averages the voltage across the entire width of the Hall element 110, which can give rise to a loss of resolution.

The present disclosure proposes a novel Hall sensor comprising first and second sets of sense electrodes disposed at opposed sides of a Hall element. The first and second sets of sense electrodes each comprise a plurality of separate and electrically isolated sense electrodes. The electrical isolation between the separate sense electrodes enables the separate sense electrodes to sit at different potentials, which alters the flow of current in the Hall sensor, in comparison to the Hall sensor arrangement of FIG. 2 in which the sense electrodes are electrically coupled together. A composite Hall voltage is determined based on the sum of voltages at the individual sense electrodes of the first set and the sum of voltages at the individual sense electrodes of the second set.

The Hall sensor of the present disclosure enables more precise detection of the Hall voltage than the Hall sensor arrangements shown in FIGS. 1 and 2 by mitigating potential non-uniformities in the distribution of the Hall field across the Hall element and increasing a signal to noise ratio of the Hall voltage.

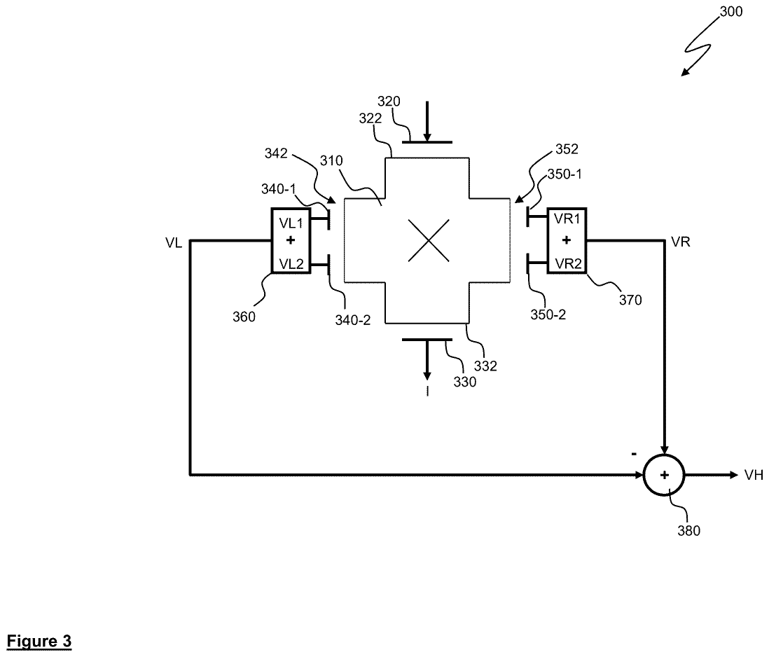

FIG. 3 is a schematic representation of an example Hall sensor arrangement according to the present disclosure.

The Hall sensor arrangement, shown generally at 300 in FIG. 3 includes a planar Hall element 310 formed of a conductor or semiconductor material such as silicon or Gallium Nitride (GaN). The planar Hall element may be provided by or constructed from a GaN two-dimensional electron gas (2DEG) resistor, for example. The Hall element 310 in this example is in the form of a cross-or plus-shaped polygon, but it will be appreciated by those of ordinary skill in the art that the Hall element 310 could be of a different polygonal shape, e.g. octagonal.

The Hall sensor arrangement 300 further includes a first bias or drive electrode 320 disposed at a first side 322, which in this example is an upper side, of the Hall element 310 and a second bias or drive electrode 330 disposed at an opposed second side 332, which in this example is a lower side, of the Hall element 310. In use of the Hall sensor arrangement 300, a bias current I (or a bias voltage) is supplied to the Hall element 310 and a current flows through the Hall element 310 between the first and second bias or drive electrodes 320, 330.

The Hall sensor arrangement 300 further includes a first set of sense electrodes comprising a first plurality (in this example two) of separate sense electrodes 340-1, 340-2 disposed at a third side 342, which in this example is a left side, of the Hall element 310. The separate sense electrodes 340-1, 340-2 of the first set are electrically isolated from each other and are spaced apart, with a first sense electrode 340-1 of the first set being disposed towards a first (upper) end of the third side 342 of the Hall element 310 and a second sense electrode 340-2 of the first set being disposed towards a second (lower) end of the third side 342 of the Hall element 310.

The Hall sensor arrangement 300 further includes a second set of sense electrodes comprising a second plurality (in this example two) of separate sense electrodes 350-1, 350-2 disposed at a fourth side 352, which in this example is a right side, of the Hall element 310. The separate sense electrodes 350-1, 350-2 of the second set are electrically isolated from each other and are spaced apart, with a first sense electrode 350-1 of the second set being disposed towards a first (upper) end of the fourth side 352 of the Hall element 310 and a second sense electrode 350-2 of the second set being disposed towards a second (lower) end of the fourth side 352 of the Hall element 310.

As will be apparent from the foregoing disclosure and FIG. 3, the first and second sets of sense electrodes are disposed symmetrically about a direction of flow of bias current through the Hall element 310.

The Hall sensor arrangement 300 further includes first adder circuitry 360 having a plurality of inputs, each of which is coupled a respective one of the first plurality of separate sense electrodes 340-1, 340-2 of the first set so as to receive a sense voltage from the sense electrode. The first adder circuitry 360 may comprise analog or digital adder circuitry (and associated analog to digital converter circuitry, in the case where the first adder circuitry 360 comprises digital adder circuitry, as will be appreciated by those of ordinary skill in the art). In the example illustrated in FIG. 3, the first adder circuitry 360 has first and second inputs which receive respective sense voltages VL1, VL2 from the sense electrodes 340-1, 340-2 of the first set. The first adder circuitry 360 is configured to output a first adder output signal VL (e.g. a first combined voltage) indicative of the sum of the sense voltages received at its inputs from the sense electrodes 340-1, 340-2 of the first set.

The Hall sensor arrangement 300 further includes second adder circuitry 370 having a plurality of inputs, each of which is coupled a respective one of the second plurality of separate sense electrodes 350-1, 350-2 of the second set so as to receive a sense voltage from the sense electrode. The second adder circuitry 370 may comprise analog or digital adder circuitry (and associated analog to digital converter circuitry, in the case where the second adder circuitry 370 comprises digital adder circuitry, as will be appreciated by those of ordinary skill in the art). In the example illustrated in FIG. 3, the second adder circuitry 370 has first and second inputs which receive respective sense voltages VR1, VR2 from the sense electrodes 350-1, 350-2 of the second set. The second adder circuitry 370 is configured to output a second adder output signal VR (e.g. a second combined voltage) indicative of the sum of the sense voltages received at its inputs from the sense electrodes 350-1, 350-2 of the second set.

An output of the first adder circuitry 360 is coupled to a first input of subtractor circuitry 380 (which may comprise analog or digital subtractor circuitry) so as to supply the first adder output signal VL to the subtractor circuitry 380. An output of the second adder circuitry 370 is coupled to a second input of the subtractor circuitry 380 so as to supply the second adder output signal VR to the subtractor circuitry 380. The subtractor circuitry 380 is configured to subtract the first adder output signal VL from the second adder output signal VR to generate a composite Hall voltage signal VH, which may be output to downstream circuitry (not shown in FIG. 3) for further processing.

Thus, in contrast to the Hall sensor arrangement 200 shown in FIG. 2, the separate sense electrodes 340-1, 340-2 of the first set are not electrically coupled together, but instead supply separate sense voltages VL1, VL2 to the first adder circuitry 360, which sums the sense voltages VL1, VL2. Similarly, the separate sense electrodes 350-1, 350-2 of the second set are not electrically coupled together, but instead supply separate sense voltages VR1, VR2 to the second adder circuitry 370, which sums the sense voltages VR1, VR2.

By sensing the voltage at the plurality of separate electrically isolated sense electrodes 340-1, 340-2 of the first set and the voltage at the plurality of separate electrically isolated sense electrodes 350-1, 350-2 of the second set, the Hall sensor arrangement 300 allows for improved sensitivity and accuracy and reduced noise in determining the Hall voltage VH.

In the example Hall sensor arrangement 300 of FIG. 3, the first and second sets of sense electrodes 340-1, 340-2, 350-1, 350-2 are disposed at opposed first and second sides 342, 352 of the Hall element 310. In other examples, sense electrodes may be disposed at vertices of the Hall element 310.

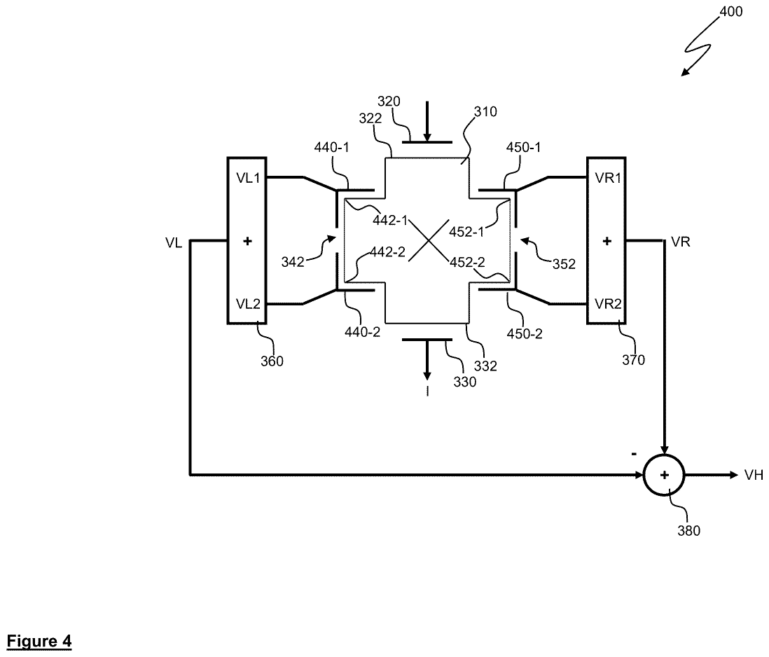

FIG. 4 is a schematic representation of a further example Hall sensor arrangement according to the present disclosure.

The Hall sensor arrangement, shown generally at 400 in FIG. 4, has a number of features in common with the Hall sensor arrangement 300 of FIG. 3. Such common features are denoted by common reference numerals in FIGS. 3 and 4 and will not be described again in detail here, for the sake of clarity and brevity.

The Hall sensor arrangement 400 differs from the Hall sensor arrangement 300 in that instead of having a first set of sense electrodes disposed at the third side 342 and a second set of sense electrodes disposed at the fourth side 352 of the Hall element 310, the Hall sensor arrangement 400 has a first set of sense electrodes comprising first and second sense electrodes 440-1, 440-2 that are disposed at outer corners or vertices of the third side 342 of the Hall element 310 and a second set of sense electrodes comprising first and second sense electrodes 450-1, 450-2 that are disposed at outer corner or vertices of the fourth side 352 of the Hall element 310.

In the example shown in FIG. 4, the first sense electrode 440-1 of the first set is disposed at an upper outer corner or vertex 442-1 of the third side 342 of the Hall element 310 and the second sense electrode 440-2 of the first set is disposed at a lower outer corner or vertex 442-2 of the third side 342 of the Hall element 310. The first and second sense electrodes 440-1, 440-2 of the first set are separate and electrically isolated from each other.

Similarly, the first sense electrode 450-1 of the second set is disposed at an upper outer corner or vertex 452-1 of the fourth side 352 of the Hall element 310, opposed to the first sense electrode 440-1 of the first set, and the second sense electrode 450-2 of the second set is disposed at a lower outer corner or vertex 452-2 of the fourth side 352 of the Hall element 310, opposed to the second sense electrode 440-2 of the first set. The first and second sense electrodes 450-1, 450-2 of the second set are separate and electrically isolated from each other.

As will be apparent from the foregoing disclosure and FIG. 4, the first and second sets of sense electrodes are disposed symmetrically about a direction of flow of bias current through the Hall element 310.

The first and second sense electrodes 440-1, 440-2 of the first set are coupled, respectively, to the first and second inputs of the first adder circuitry 360 to supply respective sense voltages VL1, VL2 to the first adder circuitry 360. The first adder circuitry 360 is configured to output a first adder output signal VL (e.g. a first combined voltage) indicative of the sum of the sense voltages received at its inputs from the sense electrodes 440-1, 440-2 of the first set.

Similarly, the first and second sense electrodes 450-1, 450-2 of the first set are coupled, respectively, to the first and second inputs of the second adder circuitry 370 to supply respective sense voltages VR1, VR2 to the second adder circuitry 370. The second adder circuitry 370 is configured to output a second adder output signal VR (e.g. a second combined voltage) indicative of the sum of the sense voltages received at its inputs from the sense electrodes 450-1, 450-2 of the second set.

As in the Hall sensor arrangement 300 of FIG. 3, the output of the first adder circuitry 360 is coupled to the first input of the subtractor circuitry 380 so as to supply the first adder output signal VL to the subtractor circuitry 380. The output of the second adder circuitry 370 is coupled to the second input of the subtractor circuitry 380 so as to supply the second adder output signal VR to the subtractor circuitry 380. The subtractor circuitry 380 is configured to subtract the first adder output signal VL from the second adder output signal VR to generate a composite Hall voltage signal VH, which may be output to downstream circuitry (not shown in FIG. 4) for further processing.

The provision of the sense electrodes 440-1, 440-2 of the first set at the outer corners or vertices 442-1, 442-2 of the third side 342 and the sense electrodes 450-1, 450-2 of the second set at the opposed outer corners or vertices 452-1, 452-2 of the fourth side 352 may give rise to lower offset the Hall sensor arrangement 400, in comparison to the Hall sensor arrangement 300 of FIG. 3, because the outer corners or vertices 442-1, 442-2, 452-1, 452-2 experience different (e.g. greater magnitude) variations in Hall voltage.

As in the Hall sensor arrangement 300 of FIG. 3, by sensing the voltage at the plurality of separate electrically isolated sense electrodes 440-1, 440-2 of the first set and the voltage at the plurality of separate electrically isolated sense electrodes 450-1, 450-2 of the second set, the Hall sensor arrangement 400 allows for improved sensitivity and accuracy and reduced noise in determining the Hall voltage VH.

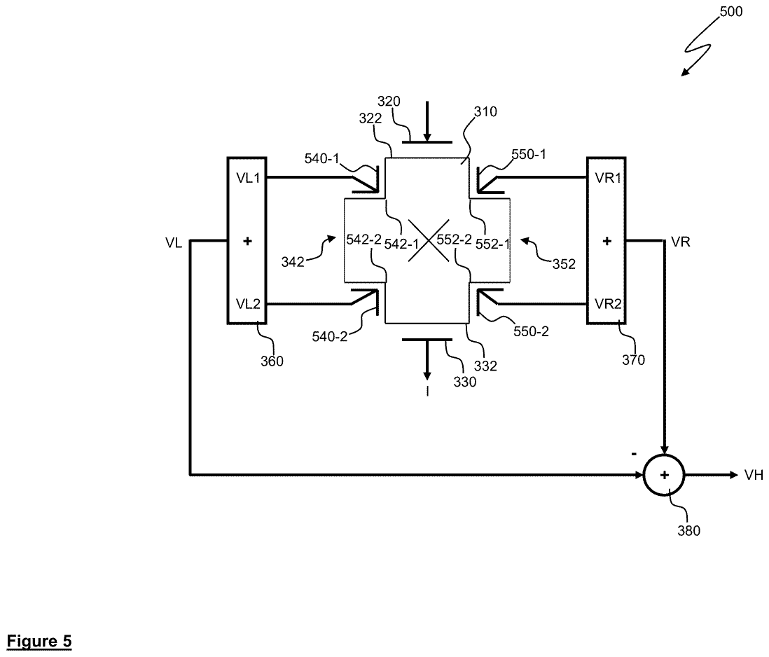

FIG. 5 is a schematic representation of a further example Hall sensor arrangement according to the present disclosure.

The Hall sensor arrangement, shown generally at 500 in FIG. 5, has a number of features in common with the Hall sensor arrangement 300 of FIG. 3 and the Hall sensor arrangement 400 of FIG. 4. Such common features are denoted by common reference numerals in FIGS. 3, 4 and 5 and will not be described again in detail here, for the sake of clarity and brevity.

The Hall sensor arrangement 500 differs from the Hall sensor arrangement 400 in that instead of having a first set of sense electrodes disposed at outer corners or vertices of the third side 342 of the Hall element 310 and a second set of sense electrodes disposed at outer corners or vertices of the fourth side 352 of the Hall element 310, the Hall sensor arrangement 500 has a first set of sense electrodes comprising first and second sense electrodes 540-1, 540-2 that are disposed at inner corners or vertices of the third side 342 of the Hall element 310 and a second set of sense electrodes comprising first and second sense electrodes 550-1, 550-2 that are disposed at inner corner or vertices of the fourth side 352 of the Hall element 310.

In the example shown in FIG. 5, the first sense electrode 540-1 of the first set is disposed at an upper inner corner or vertex 542-1 of the third side 342 of the Hall element 310 and the second sense electrode 440-2 of the first set is disposed at a lower inner corner or vertex 542-2 of the third side 342 of the Hall element 310. The first and second sense electrodes 540-1, 540-2 of the first set are separate and electrically isolated from each other.

Similarly, the first sense electrode 550-1 of the second set is disposed at an upper inner corner or vertex 552-1 of the fourth side 352 of the Hall element 310, opposed to the first sense electrode 540-1 of the first set, and the second sense electrode 550-2 of the second set is disposed at a lower inner corner or vertex 552-2 of the fourth side 352 of the Hall element 310, opposed to the second sense electrode 540-1 of the first set. The first and second sense electrodes 550-1, 550-2 of the second set are separate and electrically isolated from each other.

As will be apparent from the foregoing disclosure and FIG. 5, the first and second sets of sense electrodes are disposed symmetrically about a direction of flow of bias current through the Hall element 310.

The first and second sense electrodes 540-1, 540-2 of the first set are coupled, respectively, to the first and second inputs of the first adder circuitry 360 to supply respective sense voltages VL1, VL2 to the first adder circuitry 360. The first adder circuitry 360 is configured to output a first adder output signal VL (e.g. a first combined voltage) indicative of the sum of the sense voltages received at its inputs from the sense electrodes 540-1, 540-2 of the first set.

Similarly, the first and second sense electrodes 550-1, 550-2 of the first set are coupled, respectively, to the first and second inputs of the second adder circuitry 370 to supply respective sense voltages VR1, VR2 to the second adder circuitry 370. The second adder circuitry 370 is configured to output a second adder output signal VR (e.g. a second combined voltage) indicative of the sum of the sense voltages received at its inputs from the sense electrodes 550-1, 550-2 of the second set.

As in the Hall sensor arrangements 300, 400 of FIGS. 3 and 4, the output of the first adder circuitry 360 is coupled to the first input of the subtractor circuitry 380 so as to supply the first adder output signal VL to the subtractor circuitry 380. The output of the second adder circuitry 370 is coupled to the second input of the subtractor circuitry 380 so as to supply the second adder output signal VR to the subtractor circuitry 380. The subtractor circuitry 380 is configured to subtract the first adder output signal VL from the second adder output signal VR to generate a composite Hall voltage signal VH, which may be output to downstream circuitry (not shown in FIG. 5) for further processing.

The provision of the sense electrodes 540-1, 540-2 of the first set at the inner corners or vertices 542-1, 542-2 of the third side 342 and the sense electrodes 550-1, 550-2 of the second set at the opposed inner corners or vertices 542-1, 542-2 of the fourth side 352 allows the Hall sensor arrangement 500 to take advantage of localised field variations in the vicinity of the inner corners or vertices 541-1, 542-2, 552-1, 552-2 of the Hall element 310.

As in the Hall sensor arrangements 300, 400 of FIGS. 3 and 4, by sensing the voltage at the plurality of separate electrically isolated sense electrodes 540-1, 540-2 of the first set and the voltage at the plurality of separate electrically isolated sense electrodes 550-1, 550-2 of the second set, the Hall sensor arrangement 500 allows for improved sensitivity and accuracy and reduced noise in determining the Hall voltage VH.

The Hall sensor arrangements 300, 400, 500 of FIGS. 3, 4 and 5 may be implemented in a number of different ways.

In some examples, the whole of the Hall sensor arrangement 300, 400, 500 may be implemented in integrated circuitry, e.g. on a single integrated circuit (IC), with appropriate terminals or connections to allow the bias current I to be supplied to the first bias or drive electrode 320 and the hall voltage VH to be supplied to downstream signal conditioning and/or processing circuitry. In such examples, downstream signal conditioning and/or signal processing circuitry for conditioning or processing the Hall voltage output signal of the subtractor circuitry 380 may also implemented in the same integrated circuitry as the Hall sensor arrangement 300, 400, 500.

In other examples, the Hall element 310, the first and second bias or drive electrodes 320, 330, the sense electrodes 340-1, 340-2, 350-1, 350-2, 440-1, 440-2, 450-1, 450-2, 540-1, 540-2, 550-1, 550-2 and the first and second adder circuitry 360, 370 are implemented in integrated circuitry (e.g. on a single IC) and the subtractor circuitry 380 is implemented externally of the integrated circuitry, i.e. off-chip.

In other examples, the Hall element 310, the first and second bias or drive electrodes 320, 330, the sense electrodes 340-1, 340-2, 350-1, 350-2, 440-1, 440-2, 450-1, 450-2, 540-1, 540-2, 550-1, 550-2 are implemented in integrated circuitry and the first and second adder circuitry 360, 370 and the subtractor circuitry 380 are implemented externally of the integrated circuitry, i.e. off-chip.

The Hall element 310 may be formed of any suitable conductor or semiconductor material, e.g. silicon (Si) or gallium nitride (GaN). Gallium nitride may be preferred as a material for the Hall element 310, as a Hall sensor arrangement that uses a Hall element 310 formed of gallium nitride may exhibit higher sensitivity than a Hall sensor arrangement that uses a Hall element 310 formed from another material such as silicon.

In the Hall sensor arrangements 300, 400, 500 described above with reference to FIG. 3-5, individual sense electrode voltages at the sense electrodes of the first and second sets of sensor electrodes are first summed by the first and second adder circuitry 360, 370, and then the difference between these sums of the sense electrode voltages on the first and second sides of the Hall element 310 is determined to determine the Hall voltage VH.

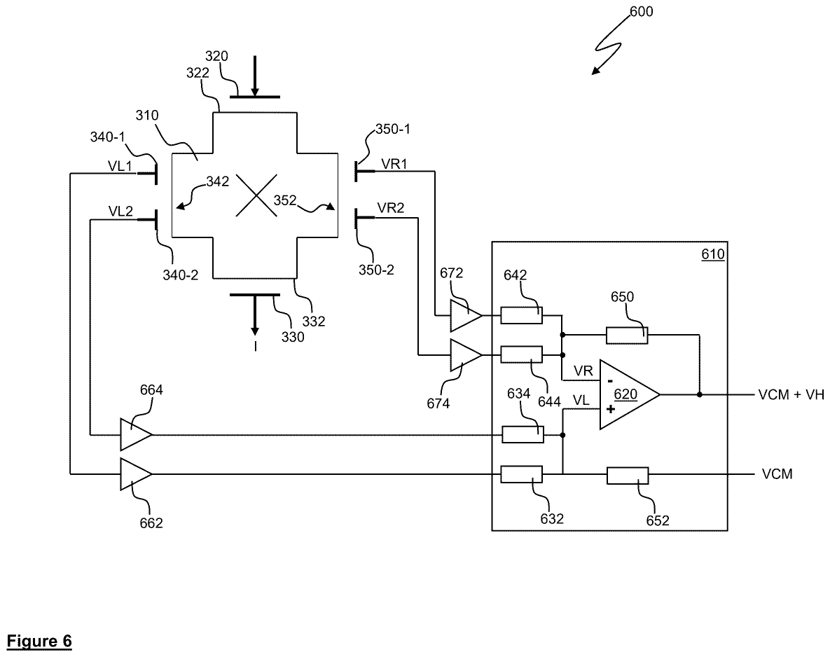

FIG. 6 is a schematic representation of an alternative Hall sensor arrangement in which summing amplifier circuitry is used to determine the sum of the sensor electrode voltages at the sense electrodes of the first and second sets and the differences between these sums.

The Hall sensor arrangement, shown generally at 600 in FIG. 6 has a number of features in common with the Hall sensor arrangement 300. Such common features are denoted by common reference numerals in FIGS. 3 and 6 and will not be described again in detail here, for the sake of clarity and brevity.

The Hall sensor arrangement 600 differs from the Hall sensor arrangement 300 in that it omits the first and second adder circuitry 360, 370. Instead, the Hall sensor arrangement 600 includes differential summing amplifier circuitry 610, which in this example includes an operational amplifier (op-amp) 720, first, second, third and fourth input resistors 632, 634, 642, 644, a feedback resistor 650, and a common mode resistor 652.

The first sense electrode 340-1 of the first set is coupled to a non-inverting (+) input of the op-amp 620 by the first input resistor 632, and the second sense electrode 340-2 of the first set is coupled to the non-inverting input of the op-amp 620 by the second input resistor 634, which is of equal resistance to the first input resistor 632. The non-inverting input of the op-amp thus forms a first summing node for summing the sense voltages VL1, VL2 output by the first and second sense electrodes 340-1, 340-2 of the first set, to generate a first composite voltage VL.

The first sense electrode 350-1 of the second set is coupled to the inverting input (−) of the op-amp 620 by the third input resistor 642, and the second sense electrode 350-2 of the second set is coupled to the inverting input of the op-amp 620 by the fourth input resistor 644, which is of equal resistance to the first, second and third input resistors 632, 642, 644. The inverting input of the op-amp 620 thus forms a first summing node for summing the sense voltages VR1, VR2 output by the first and second sense electrodes 350-1, 350-2 of the second set to generate a second composite voltage VR.

The feedback resistor 650 couples the inverting input of the op-amp 620 to the output of the op-amp 620, and may have a resistance equal to or greater than the resistances of the first to fourth input resistors 632, 634, 642, 644. As will be appreciated by those of ordinary skill in the art, if the resistance of the feedback resistor 650 is greater than the resistances of the first to fourth input resistors 632, 634, 642, 644, the differential summing amplifier circuitry 610 will have a positive gain. The common mode resistor 652 may have a resistance equal to the resistance of the feedback resistor 650.

The op-amp 620 is operative to output an output voltage VCM +VH having a common mode component VCM and a Hall voltage component VH indicative of a difference between the first composite voltage VL at its non-inverting input and the second composite voltage VR at its non-inverting input. In this way the op-amp 620 is operative to output a signal indicative of the Hall voltage VH that can be supplied to downstream signal conditioning and/or signal processing circuitry (not shown in FIG. 6).

In some examples, the Hall sensor arrangement 600 may include first, second, third and fourth buffer circuitry 662, 664, 672, 674. In the example shown in FIG. 6, the first buffer circuitry 662 is coupled between the first sense electrode 640-1 of the first set and the first input resistor 632, the second buffer circuitry 664 is coupled between the second sense electrode 640-2 of the first set and the second input resistor 634, the third buffer circuitry 672 is coupled between the first sense electrode 350-1 of the second set and the third input resistor 642, and the fourth buffer circuitry 674 is coupled between the second sense electrode 350-2 of the second set and the fourth input resistor 644. The first, second, third and fourth buffer circuitry 662, 664, 672, 674 ensures that minimal current flows through the sense electrodes 340-1, 340-2, 350-1, 350-2.

If the Hall element 310 has a low resistance (e.g. of the order of 10 Ω) and the resistance of the input resistors 632-644 is significantly greater, the buffer circuitry 662 -674 may not be required. However, if the Hall element 310 has a high resistance, the buffer circuitry 662-674 can prevent unwanted loading effects.

As in the Hall sensor arrangements 300, 400, 500 of FIG. 3-6, by sensing the voltage at the plurality of separate electrically isolated sense electrodes 340-1, 340-2 of the first set and the voltage at the plurality of separate electrically isolated sense electrodes 350-1, 350-2 of the second set, the Hall sensor arrangement 600 allows for improved sensitivity and accuracy and reduced noise in determining the Hall voltage VH.

FIG. 6 shows the sense electrodes 340-1, 340-2 of the first set and the sense electrodes 440-1, 440-2 of the second set as being disposed, respectively, at the first and second sides 342, 352 of the Hall element 310. It will be appreciated by those of ordinary skill in the art that the differential summing amplifier circuitry 610 of the Hall sensor arrangement 600 could equally be used in place of the first and second adder circuitry 360, 370 in a Hall sensor arrangement 400 of the kind shown in FIG. 4 that has sense electrodes at outer corners or vertices of the Hall element 310, or in a Hall sensor arrangement 500 of the kind shown in FIG. 5 that has sense electrodes at inner corners or vertices of the Hall element 310.

The Hall sensor arrangement 600 of FIG. 6 may be implemented in a variety of ways.

In some examples, the whole of the Hall sensor arrangement 600 may be implemented in integrated circuitry, e.g. on a single integrated circuit (IC), with appropriate terminals or connections to allow the bias current I to be supplied to the first bias or drive electrode 320 and the op-amp output signal indicative of the hall voltage VH to be supplied to downstream signal conditioning and/or processing circuitry. In such examples, downstream signal conditioning and/or signal processing circuitry for conditioning or processing the output signal of the op-amp 620 may also implemented in the same integrated circuitry as the Hall sensor arrangement 600.

In other examples, the Hall element 310, the first and second bias or drive electrodes 320, 330, and the sense electrodes 340-1, 340-2, 350-1, 350-2 are implemented in integrated circuitry, e.g. in a single IC, and the differential summing amplifier circuitry 610 externally of the integrated circuitry, i.e. off-chip.

In use of known Hall sensor arrangements, a process commonly referred to as “spinning” may be performed to eliminate or reduce offset that may arise due to imperfections in the Hall element. In a spinning process, the electrical connections to the Hall element are “rotated”, e.g. in 90 degree steps, to perform a plurality (e.g. 4) measurements per Hall voltage measurement.

For example, in use of the Hall sensor arrangement 100 of FIG. 1, in a first measurement step, a bias current (or voltage) is supplied to the Hall element 110 in a “top to bottom” direction from the first bias or drive electrode 120 to the second bias or drive electrode 130, and a Hall voltage VH indicative of the difference between a voltage that develops at the second sense electrode 150 and a voltage that develops at the first sense electrode 140 is output by the subtractor 160.

In a second measurement step, a bias current (or voltage) is supplied to the Hall element 110 in a “right to left” direction from the second sense electrode 150 to the first sense electrode 140, and a Hall voltage VH indicative of the difference between a voltage that develops at the second bias or drive electrode 130 and a voltage that develops at the first bias or drive electrode 120 is output by the subtractor 160.

In a third measurement step, a bias current (or voltage) is supplied to the Hall element 110 in a “bottom to top” direction from the second bias or drive electrode 130 to the first bias or drive electrode 120, and a Hall voltage VH indicative of the difference between a voltage that develops at the first sense electrode 140 and a voltage that develops at the second sense electrode 150 is output by the subtractor 160.

In a fourth measurement step, a bias current (or voltage) is supplied to the Hall element 110 in a “left to right” direction from the first sense electrode 140 to the second sense electrode 150, and a Hall voltage VH indicative of the difference between a voltage that develops at the first bias or drive electrode 120 and a voltage that develops at the second bias or drive electrode 130 is output by the subtractor 160.

As will be appreciated, applying the bias voltage or current sequentially through the pairs of the drive or bias electrodes and the pairs of sense electrodes over four steps in this way has the same effect as rotating the Hall element (clockwise in the example discussed above) through 90 degrees per step.

The Hall voltages obtained in each of the steps can be combined to eliminate, minimise or at least reduce offset associated with imperfections in the Hall element 110 in a single composite Hall voltage measurement.

In order to perform such spinning in the Hall sensor arrangement of the present disclosure, the first and second bias or drive electrodes should be configured similarly to the first and second sets of sense electrodes, to have separate bias or drive electrodes that are electrically isolated from each other.

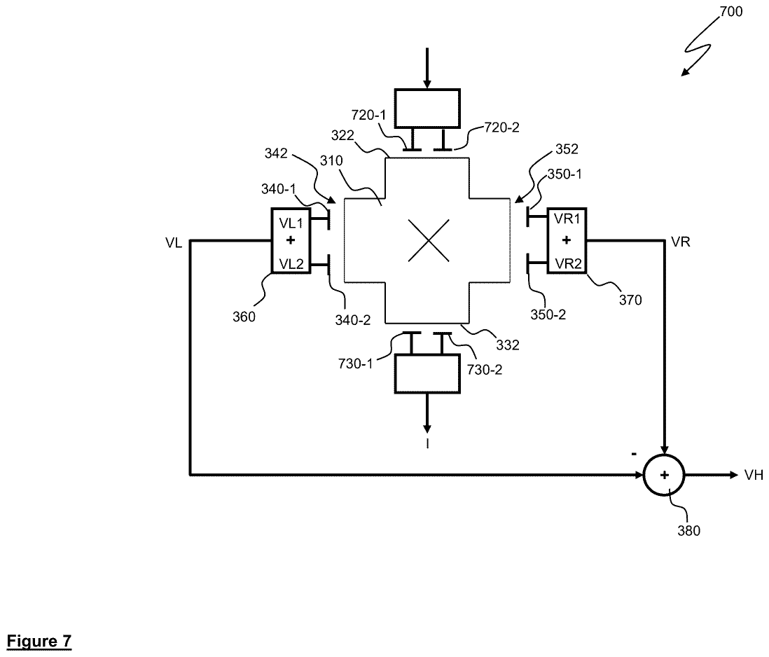

FIG. 7 is a schematic representation of a Hall sensor arrangement according to the present disclosure, having first and second sets of bias or drive electrodes of a similar configuration to first and second sets of sense electrodes.

The Hall sensor arrangement (shown generally at 700 in FIG. 7) has a number of features in common with the Hall sensor arrangement 300 of FIG. 3. Such common features are denoted by common reference numerals in FIGS. 3 and 7 and will not be described again in detail here, for the sake of clarity and brevity.

The Hall sensor arrangement 700 of FIG. 7 differs from the Hall sensor arrangement 300 of FIG. 3 in that, instead of having a single first bias or drive electrode 320 and a single second bias or drive electrode 330, the Hall sensor arrangement includes first and second sets of bias or drive electrodes, each comprising a plurality of separate bias or drive electrodes that are electrically isolated from each other.

The first set of bias or drive electrodes comprises a plurality (equal to the number of separate sense electrodes 340-1, 340-2, 350-1, 350-2 of each of the first and second sets of sense electrodes, in this example two) of separate bias or drive electrodes 720-1, 720-2 disposed at the first side 322 of the Hall element 310. The separate bias or drive electrodes 720-1, 720-2 of the first set are electrically isolated from each other.

The second set of bias or drive electrodes comprises a plurality (equal to the number of separate sense electrodes 340-1, 340-2, 350-1, 350-2 of each of the first and second sets of sense electrodes, in this example two) of separate bias or drive electrodes 730-1, 730-2 disposed at the second side 332 of the Hall element 310. The separate bias or drive electrodes 730-1, 730-2 of the first set are electrically isolated from each other.

The Hall sensor arrangement 700 is shown as including first and second adder circuitry 360, 370 and subtractor circuitry 380 of the kind described above with reference to FIG. 3, but it is to be understood that the Hall sensor arrangement could alternatively include summing amplifier circuitry of the kind described above with reference to FIG. 6 for determining the sum of the sensor electrode voltages at the sense electrodes of the first and second sets and the differences between these sums.

In use of the Hall sensor arrangement 700, a bias current or voltage is supplied to the Hall element 310 via the first and second sets of bias or drive electrodes, and the resulting Hall voltage is determined based on the voltages that develop at the separate sense electrodes 340-1, 340-2, 350-1, 350-2 of the first and second sets of sense electrodes, as described above with reference to FIG. 3 (or with reference to FIG. 6, if summing amplifier circuitry is provided in place of adder circuitry).

Because the first and second sets of bias or drive electrodes are of a similar configuration as the first and second sets of sense electrodes, in the sense that the first and second sets of bias electrodes each comprise a number of separate and electrically isolated bias or drive electrodes (which is equal to the number of separate sense electrodes of each of the first and second sets of sense electrodes), a spinning process of the kind described above can be performed in use of the Hall sensor arrangement 700, to eliminate or at least reduce offset in the Hall voltage that may otherwise arise due to imperfections in the Hall element 310.

It will be appreciated that the separate bias or drive electrodes of the first and second sets of bias or drive electrodes should be positioned (with respect to the Hall element 310) similarly to the first and second sets of sense electrodes, to enable consistent Hall voltage measures during a spinning operation. For example, in a Hall sensor arrangement having sense electrodes disposed at outer corners or vertices of the Hall element 310 (as in the Hall sensor arrangement 400 described above with reference to FIG. 4), the first bias or drive electrode 720-1 of the first set may be positioned at a left-most outer corner of the first (upper) side 322 of the Hall element 310 and the second bias or drive electrode 720-2 of the first set may be positioned at a right-most outer corner of the first (upper) side 322 of the Hall element 310. Similarly, the first bias or drive electrode 730-1 of the second set may be positioned at a left-most outer corner of the second (lower) side 332 of the Hall element 310 and the second bias or drive electrode 720-2 of the first set may be positioned at a right-most outer corner of the second (lower) side 332 of the Hall element 310.

The hall sensor arrangements 700 of FIG. 7 may be implemented in a number of different ways.

In some examples, the whole of the Hall sensor arrangement 700 may be implemented in integrated circuitry, e.g. on a single integrated circuit (IC), with appropriate terminals or connections to allow the bias current I (or voltage) to be supplied to the bias or drive electrodes 720-1, 720-2 and the hall voltage VH to be supplied to downstream signal conditioning and/or processing circuitry. In such examples, downstream signal conditioning and/or signal processing circuitry for conditioning or processing the Hall voltage output signal of the subtractor circuitry 380 (or summing amplifier circuitry, where provided) may also implemented in the same integrated circuitry as the Hall sensor arrangement 700.

In other examples, the Hall element 310, the bias or drive electrodes 720-1, 720-2, 730-1, 730-2, the sense electrodes 340-1, 340-2, 350-1, 350-2 and the first and second adder circuitry 360, 370 are implemented in integrated circuitry (e.g. on a single IC) and the subtractor circuitry 380 (or summing amplifier circuitry, where provided) is implemented externally of the integrated circuitry, i.e. off-chip.

In other examples, the Hall element 310, the bias or drive electrodes 720-1, 720-2, 730-1, 730-2 and the sense electrodes 340-1, 340-2, 350-1, 350-2 are implemented in integrated circuitry and the first and second adder circuitry 360, 370 and the subtractor circuitry 380 (or summing amplifier circuitry, where provided) are implemented externally of the integrated circuitry, i.e. off-chip.

The Hall element 310 may be formed of any suitable conductor or semiconductor material, e.g. silicon (Si) or gallium nitride (GaN). Gallium nitride may be preferred as a material for the Hall element 310, as a Hall sensor arrangement that uses a Hall element 310 formed of gallium nitride may exhibit higher sensitivity than a Hall sensor arrangement that uses a Hall element 310 formed from another material such as silicon.

In the examples illustrated in FIG. 3-7 each set of sense electrodes includes two separate and electrically isolated sense electrodes (and in the example illustrated in FIG. 7 each set of bias or drive electrodes includes two separate and electrically isolated bias or drive electrodes). It is to be understood that each set of sense electrodes could include more than two separate sense electrodes, and similarly each set of bias or drive electrodes could include more than two separate bias or drive electrodes, provided that the number of separate bias or drive electrodes in each set of bias or drive electrodes is equal to the number of separate sense electrodes in each set of sense electrodes, and the configuration and positioning of the sets of bias or drive electrodes relative to the Hall element 310 are similar to or correspond to the configuration and positioning of the sets of sense electrodes relative to the Hall element 310, to permit the use of a spinning process to eliminate or reduce offset in Hall voltage measurements.

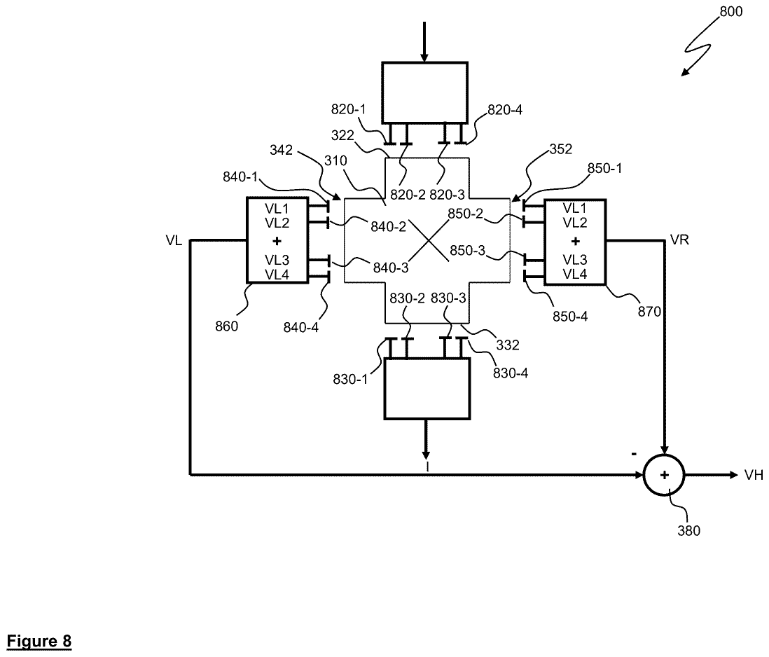

FIG. 8 is a schematic representation of a Hall sensor arrangement according to the present disclosure, having first and second sets of four bias or drive electrodes of a similar configuration to first and second sets of four sense electrodes.

The Hall sensor arrangement (shown generally at 800 in FIG. 8) has a number of features in common with the Hall sensor arrangement 700 of FIG. 7. Such common features are denoted by common reference numerals in FIGS. 7 and 8 and will not be described again in detail here, for the sake of clarity and brevity.

The Hall sensor arrangement 800 differs from the Hall sensor arrangement 800 in that the first and second sets of bias or drive electrodes each comprise more than two (in this example four) electrodes.

Thus, as shown in FIG. 8, the first set of bias or drive electrodes includes first, second, third and fourth bias or drive electrodes 820-1, 820-2, 820-3, 820-4, which are electrically isolated from each other. The first and second bias or drive electrodes 820-1, 820-2 of the first set are positioned towards a first (left) end of the first (upper) side 322 of the Hall element 310, while the third and fourth bias or drive electrodes are positioned towards a second (right) end of the first (upper) side 322 of the Hall element 310, with no bias or drive electrodes being positioned in the centre of the first (upper) side 322 of the Hall element 310.

Similarly, the second set of bias or drive electrodes includes first, second, third and fourth bias or drive electrodes 830-1, 830-2, 830-3, 830-4, which are electrically isolated from each other. The first and second bias or drive electrodes 830-1, 830-2 of the second set are positioned towards a first (left) end of the second (lower) side 332 of the Hall element 310, while the third and fourth bias or drive electrodes are positioned towards a second (right) end of the second (lower) side 332 of the Hall element 310, with no bias or drive electrodes being positioned in the centre of the second (lower) side 332 of the Hall element 310.

The first set of sense electrodes includes first, second, third and fourth sense electrodes 840-1, 840-2, 840-3, 840-4, which are electrically isolated from each other. The first and second sense electrodes 840-1, 840-2 of the first set are positioned towards a first (upper) end of the third (left) side 342 of the Hall element 310, while the third and fourth bias or drive electrodes are positioned towards a second (lower) end of the third (left) side 342 of the Hall element 310, with no bias or drive electrodes being positioned in the centre of the third (left) side 342 of the Hall element 310.

Similarly, the second set of sense electrodes includes first, second, third and fourth sense electrodes 850-1, 850-2, 850-3, 850-4, which are electrically isolated from each other. The first and second sense electrodes 850-1, 850-2 of the second set are positioned towards a first (upper) end of the fourth (right) side 352 of the Hall element 310, while the third and fourth bias or drive electrodes are positioned towards a second (lower) end of the fourth (right) side 352 of the Hall element 310, with no bias or drive electrodes being positioned in the centre of the fourth (right) side 352 of the Hall element 310.

Thus, in the Hall sensor arrangement 800 of FIG. 8, the number of separate bias or drive electrodes in each set of bias or drive electrodes is equal to the number of separate sense electrodes in each set of sense electrodes, and the configuration and positioning of the sets of bias or drive electrodes relative to the Hall element 310 are similar to or correspond to the configuration and positioning of the sets of sense electrodes relative to the Hall element.

Other examples may include three separate and electrically isolated bias or drive electrodes in each set of bias or drive electrodes and three separate and electrically isolated sense electrodes in each set of sense electrodes. However, an even number of electrodes per set of bias or drive electrodes and per set of sense electrodes (where the number of electrodes in each set is equal) may be permit more effective Hall voltage measurement than an odd number of electrodes per set, as little signal may be present at a central electrode of a set comprising an odd number of electrodes.

In use of the Hall sensor arrangement 800, a bias current or voltage is supplied to the Hall element 310 via the first and second sets of bias or drive electrodes, and the resulting Hall voltage is determined based on the voltages that develop at the separate sense electrodes 840-1-840-4, 850-1-850-4 of the first and second sets of sense electrodes, as described above with reference to FIG. 3 (or with reference to FIG. 6, if summing amplifier circuitry is provided in place of adder circuitry).

The Hall sensor arrangement 800 is shown as including first and second adder circuitry 360, 370 and subtractor circuitry 380 of the kind described above with reference to FIG. 3, but it is to be understood that the Hall sensor arrangement could alternatively include summing amplifier circuitry of the kind described above with reference to FIG. 6 for determining the sum of the sensor electrode voltages at the sense electrodes of the first and second sets and the differences between these sums.

The Hall sensor arrangements 800 of FIG. 8 may be implemented in a number of different ways.

In some examples, the whole of the Hall sensor arrangement 800 may be implemented in integrated circuitry, e.g. on a single integrated circuit (IC), with appropriate terminals or connections to allow the bias current I (or voltage) to be supplied to the bias or drive electrodes 820-1-820-4 and the hall voltage VH to be supplied to downstream signal conditioning and/or processing circuitry. In such examples, downstream signal conditioning and/or signal processing circuitry for conditioning or processing the Hall voltage output signal of the subtractor circuitry 380 (or summing amplifier circuitry, where provided) may also implemented in the same integrated circuitry as the Hall sensor arrangement 800.

In other examples, the Hall element 310, the bias or drive electrodes 820-1-820-1, 830-1-830-4, the sense electrodes 840-1-840-4, 850-1-850-4 and the first and second adder circuitry 360, 370 are implemented in integrated circuitry (e.g. on a single IC) and the subtractor circuitry 380 (or summing amplifier circuitry, where provided) is implemented externally of the integrated circuitry, i.e. off-chip.

In other examples, the Hall element 310, the bias or drive electrodes 820-1-820-1, 830-1-830-4 and the sense electrodes 840-1-840-4, 850-1-850-4 are implemented in integrated circuitry and the first and second adder circuitry 360, 370 and the subtractor circuitry 380 (or summing amplifier circuitry, where provided) are implemented externally of the integrated circuitry, i.e. off-chip.

The Hall element 310 may be formed of any suitable conductor or semiconductor material, e.g. silicon (Si) or gallium nitride (GaN). Gallium nitride may be preferred as a material for the Hall element 310, as a Hall sensor arrangement that uses a Hall element 310 formed of gallium nitride may exhibit higher sensitivity than a Hall sensor arrangement that uses a Hall element 310 formed from another material such as silicon.

When a magnetic field is applied to a Hall sensor arrangement 100 of the kind shown in FIG. 100 (while a bias current or voltage is being applied to the Hall sensor arrangement 100), a voltage gradient is seen along the sense electrodes 140, 150. The voltage increases towards the ends of the sense electrodes 140, 150, with little or no voltage being present at a centre portion of the sense electrodes 140, 150. This suggests that the centre portion of each of the sense electrodes 140, 150 contains no signal but may still be a source of offset and noise.

In a Hall sensor arrangement according to the present disclosure having first and second sets of separate and electrically isolated sense electrodes, e.g. in the Hall sensor arrangement 300 of FIG. 3 which has a first set of separate sense electrodes 340-1, 340-2 and a second set of separate sense electrodes 350-1, 350-2, the sense electrodes 340-1, 340-2, 350-1, 350-2 are positioned towards the ends of the respective first and second sides 342, 352 of the Hall element 310, with no sense electrode being positioned in a central portion of a side of the Hall element 310. Consequently, there should be less offset in the voltages at the sense electrodes 340-1, 340-2, 350-1, 350-2, and it is possible to eliminate, minimise or at least reduce any offset in the voltages at the sense electrodes 340-1, 340-2, 350-1, 350-2 by applying suitable weighing to those voltages when summing the sense voltages VL1, VL2 at the first set of sense electrodes and when summing the sense voltages VR1, VR2 at the second set of sense electrodes.

A first set of weights to be applied to the sense voltages VL1, VL2 when a bias current or voltage is applied in a “top to bottom” direction (i.e., from the first bias or drive electrode 320 to the second bias or drive electrode 330) may be determined during a calibration operation for the Hall sensor arrangement 300. Similarly, a second set of weights to be applied to the sense voltages VR1, VR2 when a bias current or voltage is applied in a “top to bottom” direction may be determined during the calibration operation for the Hall sensor arrangement 300.

In the calibration operation, a known bias voltage or current is applied to the Hall element 310 in the “top to bottom” direction with the Hall sensor arrangement 300 in the presence of a known magnetic field, and the voltages VL1, VL2, VR1, VR2 are measured. These measured voltages are compared to expected voltages to determine offset values, from which weights to be applied to each of the voltages VL1, VL2, VR1, VR2 in operation of the Hall sensor arrangement 300 can be calculated and stored, e.g. in a memory of the Hall sensor arrangement 300 or a memory of a host device incorporating the Hall sensor arrangement 300.

A third set of weights to be applied to the sense voltages VL1, VL2 when a bias current or voltage is applied in a “bottom to top” direction (i.e., from the second bias or drive electrode 330 to the first bias or drive electrode 320) may be determined during the calibration operation for the Hall sensor arrangement 300. Similarly, a fourth set of weights to be applied to the sense voltages VR1, VR2 when a bias current or voltage is applied in a “bottom to top” direction may be determined during the calibration operation for the Hall sensor arrangement 300.

In the calibration operation, a known bias voltage or current is applied to the Hall element 310 in the “bottom to top” direction with the Hall sensor arrangement 300 in the presence of the known magnetic field, and the voltages VL1, VL2, VR1, VR2 are measured. These measured voltages are compared to expected voltages to determine offset values, from which weights to be applied to each of the voltages VL1, VL2, VR1, VR2 in operation of the Hall sensor arrangement 300 can be calculated and stored, e.g. in the memory of the Hall sensor arrangement 300 or a memory of a host device incorporating the Hall sensor arrangement 300.

The weights may be applied to the sense voltages VL1, VL2, VR1, VR2 by the first and second adder circuitry 360, 370 in use of the Hall sensor arrangement for a Hall voltage measurement. Thus, the first adder circuitry 360 may be configured to perform a weighted sum of the sense voltages VL1, VL2 and the second adder circuitry 370 may be configured to perform a weighted sum of the sense voltages VR1, VR2.

Calculating and applying weights to the sense voltages VL1, VL2, VR1, VR2 may obviate the need for a spinning operation to eliminate or reduce offset in the Hall voltage VH output by the Hall sensor arrangement 300, as offset is cancelled or reduced by the application of the weights to the sense voltages VL1, VL2, VR1, VR2.

In some examples, the direction of the bias current or voltage may alternate between “top to bottom” and “bottom to top”, and the corresponding sets of weights for the sense voltages are selected and applied to the sense voltages VL1, VL2, VR1, VR2 (i.e. the first and second sets of weights are selected and applied when the bias current or voltage is applied in a “top to bottom direction” and the third and fourth sets of weights are selected and applied when the bias current or voltage is applied in the bottom to top direction).

It will be appreciated that a similar process of determining and applying weights may be used in the Hall sensor arrangements 400, 500, 600, 700, 800 of FIGS. 4-8 to eliminate, minimise or at least reduce offset in Hall voltage measurements.

The Hall sensor arrangements described above with reference to the accompanying drawings may be incorporated in a host device such as a laptop, notebook, netbook or tablet computer, a gaming device such as a games console or a controller for a games console, a virtual reality (VR) or augmented reality (AR) device, a mobile telephone, a portable audio player or some other portable device, or may be incorporated in an accessory device for use with a laptop, notebook, netbook or tablet computer, a gaming device, a VR or AR device, a mobile telephone, a portable audio player or other portable device.

The skilled person will recognise that some aspects of the above-described apparatus and methods may be embodied as processor control code, for example on a non-volatile carrier medium such as a disk, CD-or DVD-ROM, programmed memory such as read only memory (Firmware), or on a data carrier such as an optical or electrical signal carrier. For many applications embodiments of the invention will be implemented on a DSP (Digital Signal Processor), ASIC (Application Specific Integrated Circuit) or FPGA (Field Programmable Gate Array). Thus the code may comprise conventional program code or microcode or, for example code for setting up or controlling an ASIC or FPGA. The code may also comprise code for dynamically configuring re-configurable apparatus such as re-programmable logic gate arrays. Similarly the code may comprise code for a hardware description language such as Verilog™ or VHDL (Very high speed integrated circuit Hardware Description Language). As the skilled person will appreciate, the code may be distributed between a plurality of coupled components in communication with one another. Where appropriate, the embodiments may also be implemented using code running on a field-(re)programmable analogue array or similar device in order to configure analogue hardware.

Note that as used herein the term module shall be used to refer to a functional unit or block which may be implemented at least partly by dedicated hardware components such as custom defined circuitry and/or at least partly be implemented by one or more software processors or appropriate code running on a suitable general purpose processor or the like. A module may itself comprise other modules or functional units. A module may be provided by multiple components or sub-modules which need not be co-located and could be provided on different integrated circuits and/or running on different processors.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

The following paragraphs describe aspects of the present disclosure.

A Hall element that comprises a Hall element configured to generate a Hall voltage in response to a perpendicular magnetic field; first and second sets of sensing electrodes for measuring the Hall voltage across the Hall element, wherein each set comprises a plurality of separate sensing electrodes that are electrically isolated from each other; and a summing circuit that sums the voltages measured at the individual sensing electrodes to generate a composite Hall voltage measurement.

In one implementation, voltages measured at the first set of sensing electrodes are summed to provide a first combined voltage, and voltages measured at the second set of sensing electrodes are summed to provide a second combined voltage, wherein the measured Hall voltage is determined as the difference between the first and second combined voltages.

In an alternative implementation, the summing circuit comprises a summing amplifier, where the amplifier computes the measured Hall voltage based on the difference between the summed voltages of the first and second sets of sensing electrodes.

In a preferred embodiment, the Hall element comprises first and second bias terminals for applying a bias voltage or current to the Hall element. The first and second sets of sensing electrodes are arranged along a first axis, while the bias terminals are arranged along a second axis orthogonal to the first axis.

In one implementation, the Hall element is a planar structure with a defined geometry, where the first and second sets of sensing electrodes are placed at vertices of the structure to optimise sensitivity.

By sensing multiple separate electrodes instead of a single electrode pair, the Hall sensor allows for improved sensitivity, which can be further enhanced by placement of the separate electrodes at corners or vertices of the Hall element. In addition, by splitting up the sensing electrodes into multiple electrodes, the system allows for high-impedance voltage sampling at multiple points to minimize interference with current flow.

A Hall element comprising first and second sets of sensing electrodes, wherein each set comprises multiple electrically isolated sensing electrodes.

Preferably, a summing is circuit configured to sum voltages from the first and second sets of sensing electrodes.

Preferably, a measured Hall voltage determined as the difference between the summed voltages of the first and second sets of sensing electrodes.

Preferably, there is provided an electrode arrangement where sensing electrodes are positioned at inner and/or outer corners of the Hall element.

Preferably, there is provided a high-impedance sampling system to measure electrode voltages with minimal current flow.

There is also provided a Hall element comprising: first and second sets of sensing electrodes for measuring a Hall voltage across the Hall element, wherein the first and second sets of sensing electrodes each comprise a plurality of separate sensing electrodes electrically isolated from each other, the separate sensing electrodes of the first and second sets coupled with a summing circuit to sum voltages measured at the separate sensing electrodes to generate a measured Hall voltage.

In one aspect, voltages measured at the first set of sensing electrodes are summed to provide a first combined voltage, and voltages measured at the second set of sensing electrodes are summed to provide a second combined voltage, wherein measured Hall voltage is based on the difference between the first and second combined voltages.

In an alternative aspect, the summing circuit comprises a summing amplifier, the summing amplifier configured to generate a measured Hall voltage based on the difference between the sum of voltages measured at the first set of sensing electrodes and the sum of voltages measured at the second set of sensing electrodes.

Preferably, the Hall element comprises first and second bias terminals for applying a bias voltage or current to the Hall element.

Preferably, the first and second sets of sensing electrodes are arranged along a first axis, and the bias terminals are arranged along a second axis orthogonal to the first axis.

In one implementation, the Hall element is provided as a shaped planar element defining a plurality of vertices, wherein the first and second sets of sensing electrodes are arranged at vertices of the shaped planar element.

Preferably, the first and second sets of sensing electrodes are arranged along a first axis, wherein pairs of electrodes of the first set of sensing electrodes are arranged at vertices symmetric about the first axis.

Preferably, pairs of electrodes of the second set of sensing electrodes are arranged at vertices symmetric about the first axis, wherein complimentary pairs of electrodes of the first and second sets are symmetric about a second axis orthogonal to the first axis.

As used herein, when two or more elements are referred to as “coupled” to one another, such term indicates that such two or more elements are in electrical, mechanical, or electromechanical communication, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

1. A Hall sensor comprising:
a Hall element configured to generate a Hall voltage in response to a magnetic field;
first and second sets of sense electrodes for detecting the Hall voltage,
wherein:
the first set of sense electrodes comprises a first plurality of separate sense electrodes that are electrically isolated from each other; and
the second set of sense electrodes comprises a second plurality of separate sense electrodes that are electrically isolated from each other.

2. The Hall sensor of claim 1, further comprising:
first adder circuitry configured to generate a first adder output signal indicative of a sum of output signals of the first plurality of separate sense electrodes; and
second adder circuitry configured to generate a second adder output signal indicative of a sum of output signals of the second plurality of separate sense electrodes.

3. The Hall sensor of claim 2, further comprising subtractor circuitry configured to generate a subtractor output signal indicative of a difference between the first and second adder output signals.

4. The Hall sensor of claim 1, further comprising differential summing amplifier circuitry configured to generate an amplifier output signal indicative of a difference between a sum of output signals of the first plurality of separate sense electrodes and a sum of output signals of the second plurality of separate sense electrodes.

5. The Hall sensor of claim 4, further comprising buffer circuitry coupled between outputs of the first and second sets of sense electrodes and inputs of the differential summing amplifier circuitry.

6. The Hall sensor of claim 1, wherein the first and second sets of set of sense electrodes are symmetrically disposed about a direction of bias current flow through the Hall element.

7. The Hall sensor of claim 6, wherein sense electrodes of the first set are disposed at outer corners or vertices of the first side of the Hall element and sense electrodes of the second set are disposed at outer corners or vertices of the second side of the Hall element.

8. The Hall sensor of claim 6, wherein sense electrodes of the first set are disposed at inner corners or vertices of the first side of the Hall element and sense electrodes of the second set are disposed at inner corners or vertices of the second side of the Hall element.

9. The Hall sensor of claim 1, further comprising first and second bias electrodes for supplying a bias current or voltage to the Hall element.

10. The Hall sensor of claim 9, wherein the first and second sets of sense electrodes are disposed along a first axis and the first and second bias electrodes are disposed along a second axis orthogonal to the first axis.

11. The Hall sensor of claim 1, further comprising first and second sets of bias electrodes for supplying a bias current or voltage to the Hall element, wherein:
the first set of bias electrodes comprises a first plurality of separate bias electrodes that are electrically isolated from each other;
the second set of sense electrodes comprises a second plurality of separate bias electrodes that are electrically isolated from each other; and
the first set of sense electrodes, the second set of sense electrodes, the first set of bias electrodes and the second set of bias electrodes each comprise an equal number of electrodes.

12. The Hall sensor of claim 11, wherein the first set of sense electrodes, the second set of sense electrodes, the first set of bias electrodes and the second set of bias electrodes each comprise an even number of electrodes.

13. The Hall sensor of claim 10, wherein a configuration and positioning of the first and second sets of bias electrodes relative to the Hall element are similar to or correspond to a configuration and positioning of the first and second sets of sense electrodes relative to the Hall element.

14. The Hall sensor of claim 2, wherein the first adder circuitry is configured to perform a weighted sum of the output signals of the first plurality of separate sense electrodes and the second adder circuitry is configured to perform a weighted a sum of the output signals of the second plurality of separate sense electrodes to reduce offset in an output signal of the Hall sensor indicative of the Hall voltage.

15. The Hall sensor of claim 1, wherein the Hall element comprises a planar element having a defined geometry.

16. The Hall sensor of claim 15, wherein the Hall element is in the form of a cross-or plus-shaped polygon.

17. The Hall sensor of claim 1, wherein the Hall element is of a Gallium Nitride (GaN) construction.

18. An integrated circuit comprising the Hall sensor of claim 1.

19. A host device comprising the Hall sensor of claim 1.

20. The host device of claim 19, wherein the host device comprises a laptop, notebook, netbook or tablet computer, a gaming device, a games console, a controller for a games console, a virtual reality (VR) or augmented reality (AR) device, a mobile telephone, a portable audio player, a portable device, an accessory device for use with a laptop, notebook, netbook or tablet computer, a gaming device, a games console, a VR or AR device, a mobile telephone, a portable audio player or other portable device.
